(19) United States
(12) Patent Application Publication
(10) Pub. No.: US 2006/0191668 A1
(43) Pub. Date: Aug. 31, 2006

(54) Radiator

(75) Inventor: Chen-Hui Lai, Taipei (TW)

Correspondence Address: G .LINK CO.,LTD, 3550 Bell Road, MINOOKA, IL, 60447, US

(73) Assignee: POWER COOLER ENTERPRISE CO., LTD.

(21) Appl. No.: 11/067,229

(22) Filed: Feb. 28, 2005

(51) Int. Cl. H05K 7/20

(52) U.S. Cl. 165/104.33; 165/122; 361/697; 361/700

(57) ABSTRACT

An improved radiator includes a casing unit, a fan unit, a power component, a fin unit, a conductive plate and a heat guiding pipe. The casing unit provides a front shield and a rear cover. The fan unit is received in the front shield and provides a swirl blade and connecting members in a way of the swirl blade being disposed between the front shield and the rear cover. The power component is attached to the rear cover. The fin unit is received in the front shield and disposed beside the swirl blade and provides fin parts. The heat guiding pipe has a section attached to the conductive plate to pass through the fin unit corresponding to the vertical end of the conductive plate and secure to the front shield so as to connect with the fin parts and the heat guiding pipe. Hence, heat absorbed by the conductive plate can transmit to the fin unit and allow airflow moving horizontally under operation of the fan unit to enhance heat transfer efficiency.

### BACKGROUND OF THE INVENTION

1. Field of the Invention

The present invention is related to an improved radiator and particularly to a radiator in which a volute fan is mounted horizontally in the cooling fins to allow airflow moving horizontally into and out of the fins for enhancing heat exchange efficiency.

2. Brief Description of the Related Art

In order to lower working temperature of the microprocessor or the operational chip, many ways such as using cooling fins, cooling fans and various intake and outgoing air slots provided at the computer casing have been utilized for effectively ventilating ambient air of the computer system and facilitating heat exchange of the cooling fins.

There are typical examples of the cooling fins being fixedly attached to the chip processors such as Taiwanese Patent Official Gazette Nos. 356,263 (Application No. 87,200,769), 453,472(Application No. 88,220,189), M242755 (Application No. 90,213,401), M242,756 (Application No. 90,218,045), 537,429 (Application No. 91,203,000) and 511,882 (Application No. 91,200,680).

Referring to FIG. 1, the preceding devices are made with a single or a plurality of plates with good conductivity being joined together associated with transversely and longitudinally arranged cooling fins to absorb heat and heat exchange to the air for lower temperature of the chip processor. A cooling fan can be joined to the cooling fins to speed up the heat exchange between the cooling fins and the air dragged by the cooling fan.

The prior art usually provides cooling fins with function of guiding heat being adhered to the chip and heat is dissipated by way of cooling fins indirectly contacting with air to suppress temperature increase of the chip effectively. The cooling fins can be associated with a fan to create airflow on the surfaces of the fins while the fan rotates so as to enhance heat exchange efficiency.

The implement of the fan associated with cooling fins has been utilized for several decades. The fan is disposed on top of the cooling fins and it is very possible that hot air current bounces to flow back to the fan after touching the bottom wall of the fins once the air is blown downward. As a result, the circulated air increases temperature thereof to affect convection efficiency directly. In order to overcome the preceding deficiency, Taiwanese Utility Model No. 252255, entitled “COOLING MODULE (2)” discloses a structure to allow airflow created by a rotating fan can contact with the cooling fins horizontally and hot airflow is discharged via lateral sides of the cooling fins directly. Due to the hot airflow being discharged outward horizontally, less hot airflow is sucked back to the fan so that better effect of heat convection can be obtained.

However, the fan provided in the preceding cooling module is attached to the outer side of the cooling fins and thickness of the fan results in the entire cooling module having a large volume, which is incapable of fitting with small sized main board or being received in a smaller sized casing. Thus, to reduce thickness of the individual fin or decrease the size thereof is an inevitable way has to be done. For instance, Taiwanese patent Official gazette No. 250229 entitled “HEAT DISSIPATING DEVICE” discloses a fan connecting two different sized cooling fins with a base and the fan is disposed between the big cooling fin and the small cooling fan for performing heat exchange. But, the preceding heat dissipating device provides little improvement for heat dissipation because cooling areas of the cooling fins become less o result in less area of heat exchange. Further, the fan being placed between the cooling fins affects performance of dissipating heat because center and frame of the fan are obstacles against air current passing through.

Hence, how to make a cooling device with greater airflow rate without decreasing sizes of the cooling fins for enhancing effect of convection largely is a subject worth to be cared.

### SUMMARY OF THE INVENTION

A primary object of the present invention is to provide an improved radiator, which includes a casing unit, a fan unit, a power component for actuating the fan unit, a fin unit, a heat guiding pipe and a conductive plate. The conductive plate is adhered to a chip for transmitting heat. The casing unit is composed of a front shield, which receives the fan unit and the fin unit, and a rear cover, which is attached with the power component. The fin unit provides at least a fin part horizontally disposed next to the lateral side of the swirl blade respectively. The heat guiding pipe has a horizontal section with two ends thereof being bent continuously to form a vertical end respectively such that the horizontal section can be inserted into a fitting groove preset in the conductive plate and allow the fin unit connecting with the heat guiding pipe and the conductive plate. As a result, heat generated by the chip can be transmitted to the fin unit via the conductive plate and the heat guiding pipe. The air can enter the fin unit horizontally via a lateral side of the fin part while the fan unit is in operation. Then, the air is guided to another fin part directly via the swirl blade to facilitate heat exchange. Hence, the swirl blade being disposed in the fin unit is unable to occur problems concerning impeding or decreasing airflow and reducing the sizes of the cooling fins for mounting the fan resulting from the conventional heat dissipating device.

Another object of the present invention is to provide an improved radiator, which has an extra air charging fan unit, and the fan unit provides a basin part vertically positioned at front side of the front shield corresponding to the swirl blade for receiving a fan blade and the spindle of the fan blade is joined to the swirl blade so that the fan blade and the swirl blade can rotate coaxially and airflow with low temperature is guided into the swirl blade directly to increase airflow carried by the swirl blade and to enhance heat transfer efficiency due to introducing the secondary low temperature airflow.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a perspective view of an improved radiator according to the present invention;

FIG. 2 is an exploded perspective view of the improved radiator shown in FIG. 1;

FIG. 3 is a perspective view of the improved radiator according to the present invention with a part of cutout section; and

FIG. 4 is a lateral sectional view of the improved radiator according to the present invention according to the present invention.

### DETAILED DESCRIPTION OF THE INVENTION

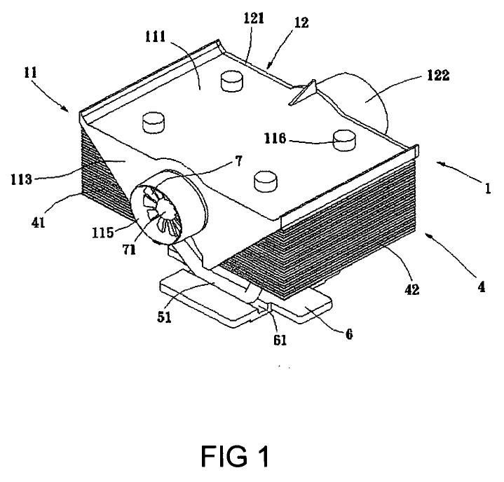

Referring to FIGS. 1 to 3, an improved radiator according to the present invention includes a casing unit 1, a fan unit 2, a power component 3 for actuating the fan unit 2, a fin unit 4, a heat guiding pipe 5 and a conductive plate 6. The conductive plate 6 is adhered to a chip (not shown) for transmitting heat.

The casing unit 1 is composed of a front shield 11, which receives the fan unit 2 and the fin unit 4, and a rear cover 12, which is attached with the power component 3. The fan unit 2 provides a rod shaped swirl blade 21 joined to a plurality of connecting members 22 and is received in a space between the frint shield and the rear cover such that the swirl blade 21 can be horizontally disposed between the front shield and rear cover.

Preferably, the front shield has a top plate 111, a bottom plate 112, a front plate 113 connecting with the top plate 111 and the bottom plate 112 and a chamber 114, which is formed between the top plate 111 and the bottom plate 112. The top plate 111 extending toward two lateral sides thereof from the center and the outer edges of the two lateral sides have a gradual upward bend respectively so that the top plate 111 is larger than the bottom in size. The bottom plate 112 has an arched lower side. The front plate 113 of the front shield 11 has an outward extending basin part 115 near central position of the outer side thereof. The rear cover 12 is formed with a plate member 121 with a shape corresponding to the front shield and a receiving part 122 disposed at the outer side of the plate member 121 for containing the power component 3. The entire configuration of the casing unit 1 is like the body of a simulated airplane.

Next, the fan unit 2 provides a rod shaped swirl blade 21 joined to a plurality of connecting members 22 and is received in the chamber 114 such that the swirl blade 21 can be horizontally disposed between the front plate 113 and the plate member 121.

Further, the connecting members 22 are composed of two connecting plates 221, 222 secured to the circumferential side of a shaft on the swirl blade 21, two shaft members 224, 225 passing through the connecting plate 221 and the front plate 225 and passing through the connecting plate 222, the plate member 121 and the power member 3 respectively and a washer 223 being passed through with the shaft member 224. The swirl blade 21 rotates horizontally in the chamber 114 by way of the connecting members 22 connecting with the power member 3.

Besides, the fin unit 4 provides two fin parts 41, 42 horizontally disposed at two lateral sides of the swirl blade 21 respectively.

The heat guiding pipe 5 has a horizontal section 51 with two ends thereof being bent continuously to form a tail section with a vertical end 52 respectively. In this way, the horizontal section 51 can be inserted into a fitting groove 61 preset in the conductive plate 6 such that the two vertical ends 52 pass through the two fin parts 41, 42 respectively and are secured to top plate 111 of the front shield 11. The top plate 111 provides a joining part 116 corresponding to respective vertical end 52 such that the fin parts 41, 42 have a relation of connection with the heat guiding pipe 5 and the conductive plate 6. As a result, heat generated by the chip (not shown) can be transmitted to the fin unit 4 via the conductive plate 6 and the heat guiding pipe 5 by way of conduction.

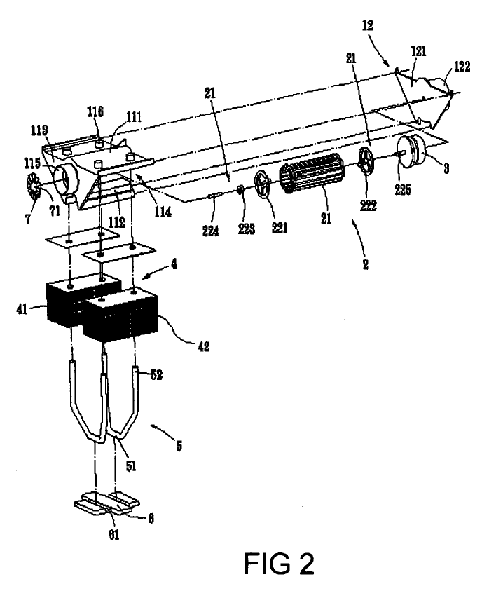

Preferably, in order to allow the heat guiding pipe 5 and the conductive plate 6 holding the casing steadily, a plurality of fitting grooves 61 can be provided at the conductive plate 6 and a plurality of heat guiding pipes 5 can be provided to correspond to the fitting groves 61 and pass through the two fin pats 41, 42 fin units so as to increase supporting points for the casing unit 1 as double heat guiding pipes 5 shown in FIG. 2. Meanwhile, increasing number of the heat guiding pipe 5 is capable of speeding up heat conduction rate relatively.

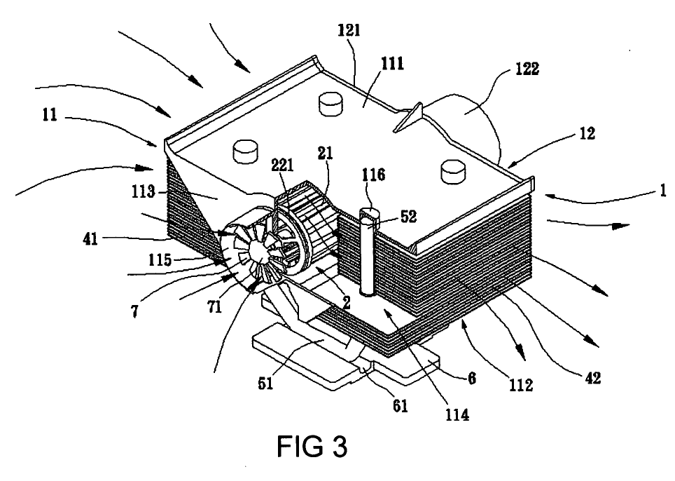

Referring to FIG. 3, once the improved radiator of the present invention is set up, the air can enter the fin unit 2 horizontally via a lateral side of the fin part 41 while the fan unit 2 is in operation. Then, the air is guided to another fin part 42 directly via the swirl blade 21 to facilitate heat exchange between the fin parts 41, 42 and allow the air with high temperature blowing outward outer side the casing unit 1 horizontally for lessening phenomenon of back heat flow.

Hence, the swirl blade 21 provided in the fin unit can solve the problems such as impeding or decreasing airflow created by the traditional blade and reducing sizes of the fins for mounting the fan so that deficiencies of the conventional radiating device can be overcome effectively.

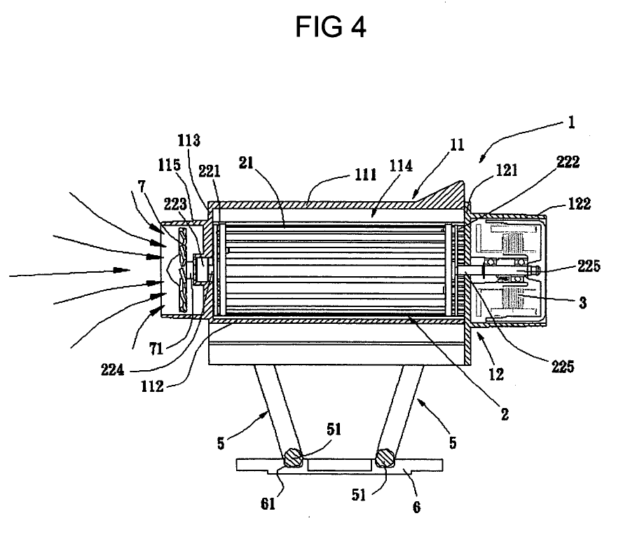

Moreover, referring to FIG. 4, the basin part 114 of the front shield 11 is provided corresponding to the swirl blade 21 and the basin part 114 is vertically disposed at the front plate 113 for receiving a fan blade 7 with a spindle 71 thereof such that the fan blade 7 and the swirl blade 21 can rotate coaxially due to the spindle 71 being exactly joined to the shaft member 224 passing through the basin 114 and the front plate 113. In this way, the airflow with low temperature is guided into the swirl blade 21 directly to increase airflow carried by the swirl blade 21 and to enhance heat transfer efficiency due to introducing the secondary low temperature airflow.

While the invention has been described with referencing to preferred embodiments thereof, it is to be understood that modifications or variations may be easily made without departing from the spirit of this invention, which is defined by the appended claims.

What is claimed is:

1. An improved radiator, comprising:
a casing unit, providing a front shield and a rear cover;
a fan unit, being received in the front shield, providing a swirl blade and a plurality of connecting members for the swirl blade being disposed between the front shield and the rear cover;
a power component, being attached to the rear cover;
a fin unit, being received in the front shield and disposed beside the swirl blade and providing fin parts;
a conductive plate; and
a heat guiding pipe, providing a section thereof at the conductive plate to pass through the fin unit corresponding to the vertical end of the conductive plate and secure to the front shield so as to connect with the fin parts and the heat guiding pipe;
whereby, the heat absorbed by the conductive plate can transmit to the fin unit and allow airflow moving horizontally under operation of the fan unit to enhance heat transfer efficiency.

2. The improved radiator as defined in claim 1, wherein the front shield has a top plate, a bottom plate, a front plate disposed between and connecting with the top plate and the bottom plate and a chamber formed between the top plate and the bottom plate.

3. The improved radiator as defined in claim 1, wherein the rear cover provides a plate member with a shape like the front shield and the outer side of the plate member provides a receiving part for containing the power component.

4. The improved radiator as defined in claim 1, wherein the swirl blade of the fan unit provides a shape of rod.

5. The improved radiator as defined in claim 1, wherein the connecting members are composed of two connecting plates secured to the circumferential side of a shaft on the swirl blade, two shaft members passing through the connecting plate and the front plate and passing through the connecting plate, the plate member and the power member respectively and a washer being passed through with the shaft member so that the swirl blade rotates horizontally in the chamber by way of the connecting members connecting with the power member

6. The improved radiator as defined in claim 1, wherein the fin unit is composed of at least a fin part to be disposed at two lateral sides of the swirl blade in way of being horizontally arranged with the swirl blade.

7. The improved radiator as defined in claim 1, wherein the heat guiding pipe has a horizontal section with two ends thereof being bent continuously to form a vertical end respectively such that the horizontal section is attached to the conductive plate and the vertical end passes through the fin part and are secured to the front shield.

8. The improved radiator as defined in claim 1, wherein the conductive plate has a fitting groove capable of being inserted and joined with the horizontal section of the heat guiding pipe.

9. The improved radiator as defined in claim 1, wherein the top plate provides a joining part corresponding to the vertical end for being inserted with the vertical end.

10. The improved radiator as defined in claim 1, wherein the conductive plate provides a plurality of fitting grooves for being attached with multiple sets of heat guiding pipes to increase support points for supporting the casing unit and enhancing heat conductive rate and facilitating heat dissipation.

11. The improved radiator as defined in claim 1, wherein a basin part is vertically provided at the front plate of the front shield corresponding to the swirl blade and the central position of the basin receives a fan blade with the spindle thereof passing through the basin and exactly joining with the shaft member between the basin part and the front plate so that the fan blade coaxially rotates with the swirl blade to allow airflow with low temperature being guided into the swirl blade 21 directly to increase airflow carried by the swirl blade.

12. The improved radiator as defined in claim 8, wherein the conductive plate provides a plurality of fitting grooves for being attached with multiple sets of heat guiding pipes to increase support points for supporting the casing unit and enhancing heat conductive rate and facilitating heat dissipation.

13. The improved radiator as defined in claim 2, wherein a basin part is vertically provided at the front plate of the front shield corresponding to the swirl blade and the central position of the basin receives a fan blade with the spindle thereof passing through the basin and exactly joining with the shaft member between the basin part and the front plate so that the fan blade coaxially rotates with the swirl blade to allow airflow with low temperature being guided into the swirl blade directly to increase airflow carried by the swirl blade.
